(19) United States
(12) Patent Application Publication
(10) Pub. No.: US 2020/0355314 A1
(43) Pub. Date: Nov. 12, 2020

(54) LED SCREEN SUPPORT

(71) Applicant: Xiamen YinQiao Optoelectronics Technology Co.,Ltd., Xiamen (CN)

(72) Inventors: Huihan RAO, Fujian (CN); Qixiang LI, Fujian (CN)

(73) Assignee: Xiamen YinQiao Optoelectronics Technology Co.,Ltd., Xiamen (CN)

(21) Appl. No.: 16/663,317

(22) Filed: Oct. 24, 2019

(30) Foreign Application Priority Data
May 6, 2019 (CN) 201910371463.1

(51) Int. Cl. F16M 11/10; H05K 5/00; H05K 5/02; F16M 11/42

(52) U.S. Cl. CPC F16M 11/10; H05K 5/0017; H05K 5/0204; G09F 9/33; H05K 5/0234; F16M 11/42; F16M 2200/066; H05K 5/0217

(57) ABSTRACT

Disclosed is an LED screen support, including a base, a fixing bracket; a connecting rod and a frame; the fixing bracket is fixed to the base and provided with a plurality of fixing positions; one end of the connecting rod is detachably connected to one of the plurality of fixing position; upper and lower sides of the frame are respectively hinged with the connecting rod and the base, and the frame is used for mounting the LED screen.

### CROSS-REFERENCE TO RELATED APPLICATION

This application claims the priority benefit of China application serial no. 201910371463.1, filed on May 6, 2019. The entirety of the above-mentioned patent application is hereby incorporated by reference herein and made a part of this specification.

### TECHNICAL FIELD

The present application relates to the technical field of LED screen supports, in particular to an LED screen support.

### BACKGROUND

The existing LED installation method usually requires a professional to install each single LED screen in a readymade cabinet in sequence to form a large-area screen, which has a complicated and long installation process, and a high labor cost. Therefore, LED display screens preset as modular display products have been appeared, and the modular products can be assembled and spliced to reduce the installation cost of LED screens. The preset LED screen support is generally adopted, and then the LED screen is fixed on the support, and a joint or an interface for splicing is arranged on the support, and the LED screen can be quickly spliced only by matching the joint of a support with the interface of the other support. However, the above-mentioned splicing supports are generally fixed on the wall surface, and cannot be moved according to users' needs, thereby restricting the usage scenario, and the angle of the LED screen cannot be adjusted in a large range according to requirements, therefore, the viewing needs at different viewing angles cannot be met.

### SUMMARY

The following is a summary of the subject matter described in detail herein, and is not intended to limit the scope of the claims.

The embodiment of the present application provides an LED screen support, including a base, a fixing bracket, a connecting rod and a frame; the fixing bracket is fixed to the base, and a plurality of fixing positions are arranged thereon; the connecting rod is detachably connected to one of the plurality of fixing positions; the frame for mounting the LED screen is hinged to the connecting rod and the base respectively at different positions.

### BRIEF DESCRIPTION OF THE DRAWINGS

In order to more clearly illustrate the technical solutions of the embodiments of the present application, the following drawings, which are to be used in the description of the embodiments, are briefly introduced:

FIG. 1 is a structural schematic diagram of an LED screen support of Embodiment 1 according to the present embodiment.

FIG. 2 is a structural schematic diagram of the LED screen support of FIG. 1 when LED screen is not installed.

FIG. 3 is a structural schematic diagram of the base, the fixing bracket and the connecting rod of FIG. 2.

FIG. 4 is a structural schematic diagram of an LED screen support of Embodiment 2 according to the present invention.

FIG. 5 is a partial structural schematic diagram of the LED screen support of FIG. 4;

FIG. 6 is a structural schematic diagram of a bottom quick-connecting mechanism of Embodiment 1 and Embodiment 2 according to the present invention.

FIG. 7 is a structural schematic diagram of a side quick-connecting mechanism of Embodiment 1 and Embodiment 2 according to the present invention.

FIG. 8 is a structural schematic diagram showing the splicing state of the LED screen support of Embodiment 1 according to the present invention.

FIG. 9 is a structural schematic diagram showing the splicing state of the LED screen support of Embodiment 2 according to the present invention.

### DETAILED DESCRIPTION

The technical solutions in the embodiments of the present application will be clearly and completely described through embodiments and with reference to the accompanying drawings.

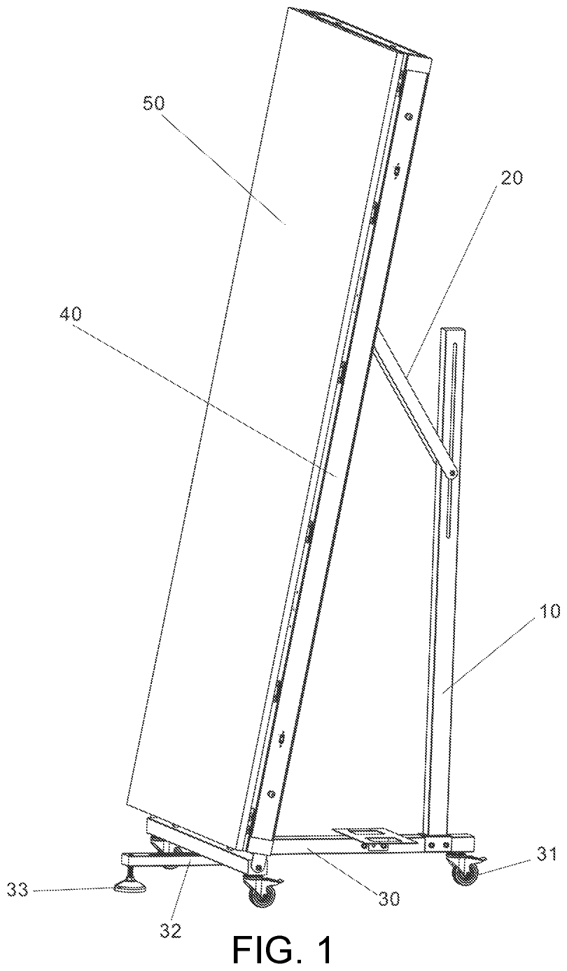

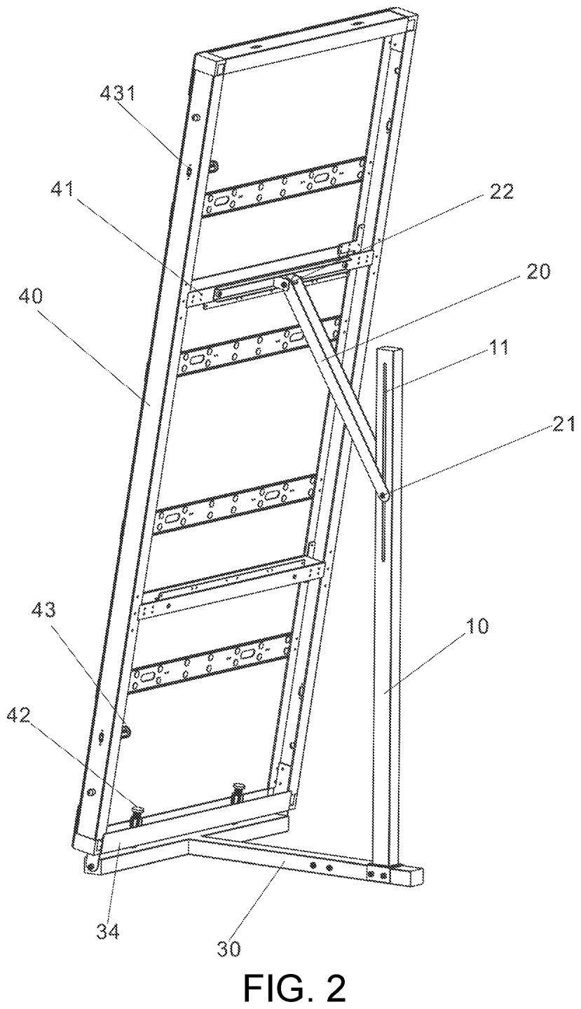

As shown in FIG. 1 and FIG. 2, the structure of the LED screen support of Embodiment 1 provided by the present invention is shown, the LED screen support mainly includes a base 30, a fixing bracket 10, a connecting rod 20, a frame 40, a bottom quick-connecting member 42, a side quick-connecting member 43, a stretching rod 32, a plurality of universal wheels 31 and a contour block 33.

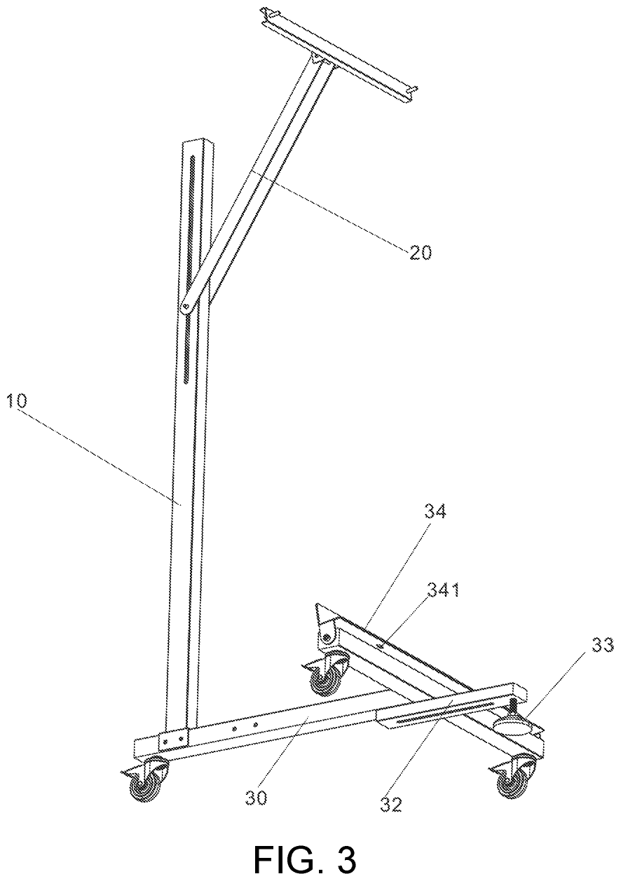

As shown in FIG. 2 and FIG. 3, the base 30 provided in Embodiment 1 is a T-shaped rod body, and three universal wheels 31 are respectively fixed at three end positions of the base 30 for driving the entire support to move. The stretching rod 32 is slidably connected to the vertical rod of the base 30 and can be pulled out or retracted below the base 30. The contour block 33 is screwed to one end of the stretching rod 32 away from the base 30, the contour block 33 can be abutted against the basement (ground) by rotating the contour block 33, thereby the position of the base 30 is fixed and the overall movement of the support is avoided.

In the Embodiment 1, the fixing bracket 10 is a rod body vertically disposed, and the bottom end of the rod body is screwed to the vertical rod of the base 30. The fixing bracket 10 is provided with a plurality of fixing positions, and the plurality of fixing positions form a sliding groove 11 disposed on the fixing bracket 10 in the embodiment, a longitudinal direction of the sliding groove 11 is the same as an extending direction of the fixing bracket 10; moreover, the sliding groove 11 is a through groove, and at the same time, a graduated scale is arranged around the sliding groove 11 of the fixing bracket 10, and the graduated scale is used to indicate the angular position of the frame 40.

In the present embodiment, a first end of the connecting rod 20 is detachably connected to one fixing position of the fixed bracket 10, and a second end of the connecting rod 20 is hinged to the frame 40. Specifically, the connecting rod 20 consists of a first rod and a second rod of the same length, a sliding shaft 21 is disposed at the first end of the connecting rod 20 near the sliding groove 11, and the sliding shaft 21 sequentially passes through the first rod, the sliding groove 11 and the second rod. The sliding shaft 21 is provided with a thread, when the sliding shaft 21 is adjusted to a proper position on the sliding groove 11, the sliding shaft 21 is screwed by a nut to fix the first end of the connecting rod 20 to the fixing bracket 10. At the same time, when it is necessary to re-adjust the position of the sliding shaft 21, the nut can be removed to allow the sliding shaft 21 to slide in the sliding groove 11.

The second end of the connecting rod 20 is hinged to the upper side of the frame 40 by a hinge shaft 22. Specifically, a first beam 41 is disposed at an upper position of the frame 40, the first beam 41 extends toward the connecting rod 20 to form two first connecting pieces, after the first rod and the second rod of the connecting rod 20 are fixed by the hinge shaft 22, the two first connecting pieces are respectively penetrated by the two ends of the hinge shaft 22, so that the connecting rod 20 is hinged to the frame 40 and the connecting rod 20 can be rotated around the hinge shaft 22 relative to the frame 40.

The bottom of the frame 40 is provided with a second beam 44, and the second beam 44 is hinged to the base 30, and the frame 40 is used to mount the preset LED screen. Specifically, the base 30 is hinged with a rotating plate 34, and the rotating plate 34 is fixed to the frame 40. Further, the rotating plate 34 is an elongated plate having an L-shaped cross section, and is provided with an abutting surface and a supporting surface, the supporting surface is close to the base 30, and the abutting surface is perpendicular to the supporting surface. Two ends of the supporting surface of the rotating plate 34 extend downward to form two second connecting pieces, the two second connecting pieces are respectively hinged to two ends of the cross bar of the base 30 by a rotating shaft, thereby, the rotating plate 34 is hinged to the base 30 and a fulcrum for the rotation of the frame 40 is provided. The abutting surface of the rotating plate 34 is used to allow the frame 40 to abut when the frame 40 is tilting toward the fixing bracket 10, thus improving the stability of the frame 40.

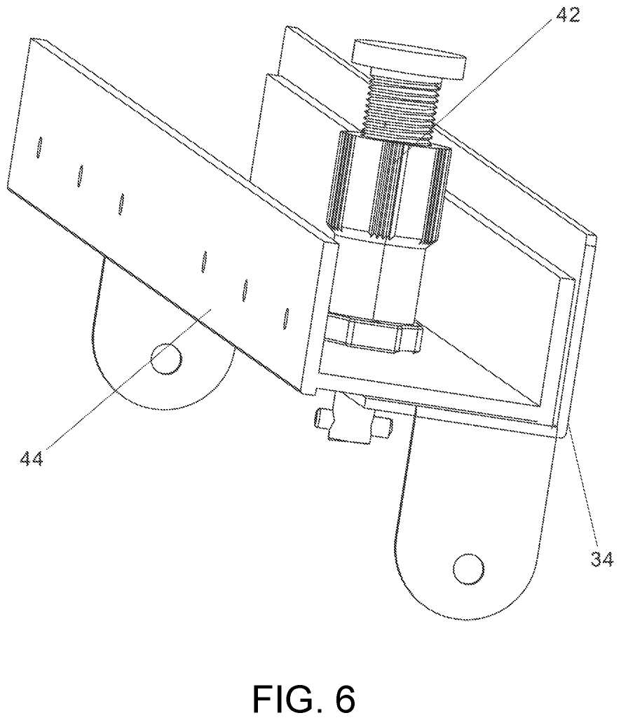

As shown in FIG. 3 and FIG. 6, a first through-hole 341 is arranged on the bottom of the rotating plate 34, and a second through-hole is arranged on a corresponding position on the second beam 44 of the frame 40. The first through-hole 341 and the second through-hole are shaped as an elongated hole. The second beam 44 on the frame 40 and the rotating plate 34 are fixedly connected by the bottom quick-connecting member 42. Specifically, the bottom quick-connecting member 42 includes a bolt and a nut, and a first clamping shaft is disposed at an end of the bolt, the first clamping shaft is two mutually symmetric protrusions protruding from the surface of the bolt, and the two protrusions are perpendicular to the extending direction of the bolt. When the fixing is performed, the nut is first screwed onto the bolt with the first clamping shaft being exposed, and the bolt is sequentially inserted through the second through-hole and the first through-hole 341, the first clamping shaft is clamped to the first through-hole 341 by rotating the bolt, the nut is then rotated downwardly against the second beam 44 to fix the second beam 44 to the rotating plate 34. It should be understood that if the bolt is sequentially inserted through the first through-hole 341 and the second through-hole, then the first clamping shaft is clamped to the second through-hole.

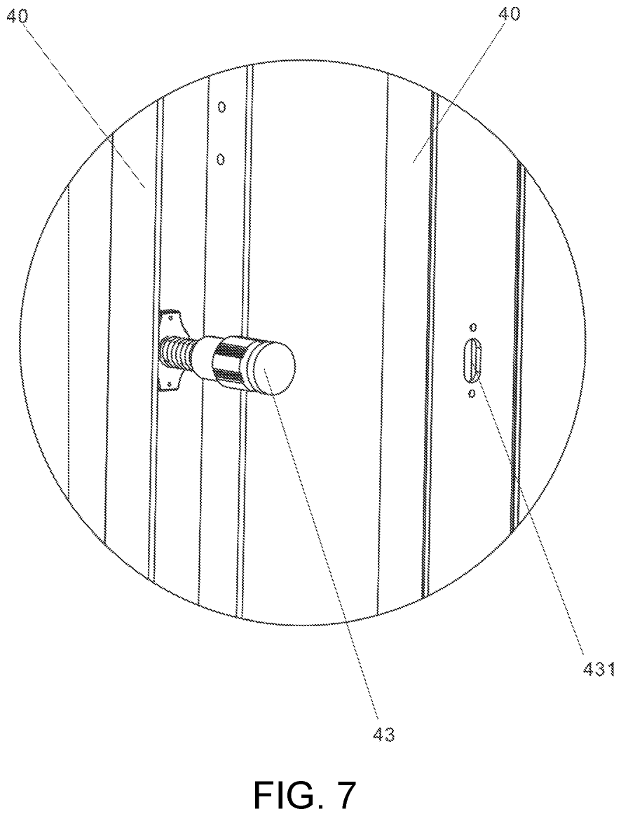

As shown in FIG. 7, two opposite third through-holes 431 are arranged on two vertical beams of the frame 40, each third through-hole 431 is shaped as an elongated through-hole. The main body of the side quick-connecting member 43 is a long shaft body, and a second clamping shaft is arranged at a first end thereof. The second clamping shaft is two mutually symmetric protrusions protruding from the surface of the long shaft body, and the two protrusions are perpendicular to the extending direction of the long shaft body. A spring is further sleeved on the long shaft body, and the second end of the long shaft body is provided with a flange structure for abutting against the spring. When it is required to splice two or more LED screen supports, the side quick-connecting member 43 is sequentially inserted through the third through-holes 431 of the first support and the second support after the third through-holes 431 of the first support and the second support are aligned with each other, and then the side quick-connecting member 43 is rotated to make the second clamping shaft to clamp the third through-hole 431 on the second support. At this time, the side quick-connecting member 43 is loosened, one end of the spring abuts against the flange on the long shaft body, and the other end of the spring abuts against the vertical beam of the frame 40 of the first support, two frames 40 of two supports are fixed by the side quick-connecting member 43 under the action of the elastic force.

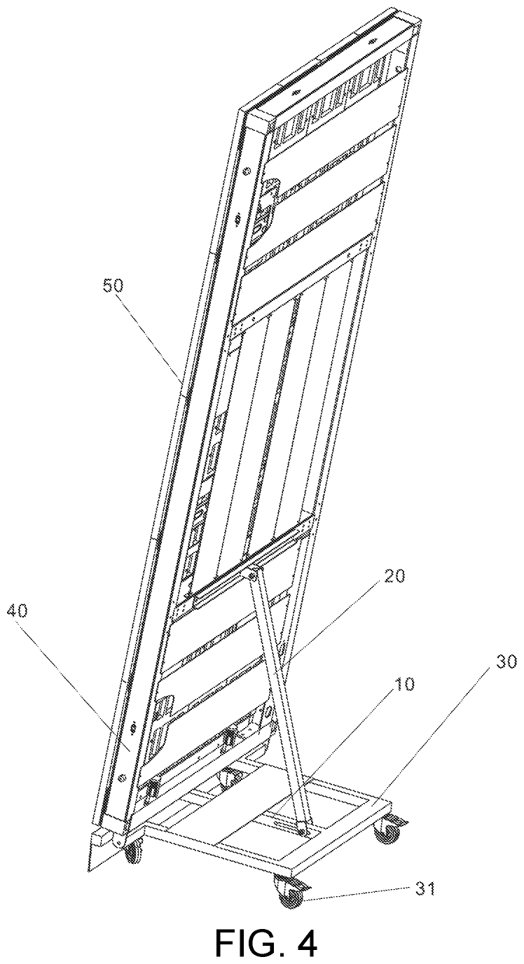

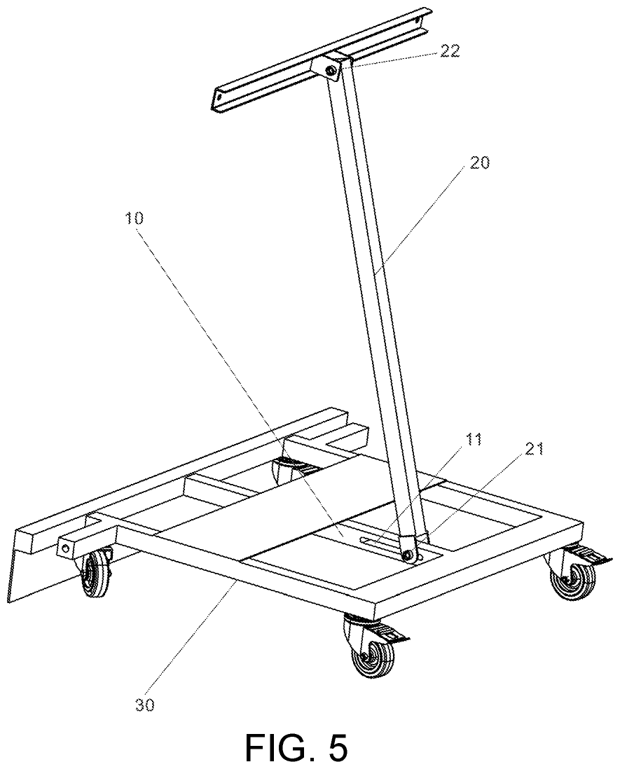

Embodiment 2 is further provided in the present invention, the difference between Embodiment 2 and Embodiment 1 is that the base 30 provided in Embodiment 2 is in a frame structure, which is specifically shown in FIG. 4 and FIG. 5, four universal wheels 31 are respectively fixed at four end positions of the base 30. The fixing bracket 10 is fixedly disposed in the frame structure of the base 30. Specifically, the fixing bracket 10 is disposed at a central position of the frame structure of the base 30, the fixing bracket 10 is a rod body parallel to the two sides of the frame structure of the base 30, and the plurality of fixing positions form a sliding groove 11 disposed on the rod body of the fixing bracket 10, a longitudinal direction of the sliding groove 11 is the same as an extending direction of the fixing bracket 10, and the connection relationship between the sliding groove 11 and the connecting rod 20 is the same as that of the Embodiment 1.

During use, a preset LED screen is mounted on the frame 40, generally by magnetic attraction. When it is required to adjust the pitch angle of the LED screen, the nut on the sliding shaft 21 is first loosened, the position of the sliding shaft 21 in the sliding groove 11 is adjusted, and then the frame 40 is rotated accordingly. When the desired angle of the frame 40 is positioned as per the graduated scale, the angular position of the frame 40 can be fixed by screwing the nut on the sliding shaft 21.

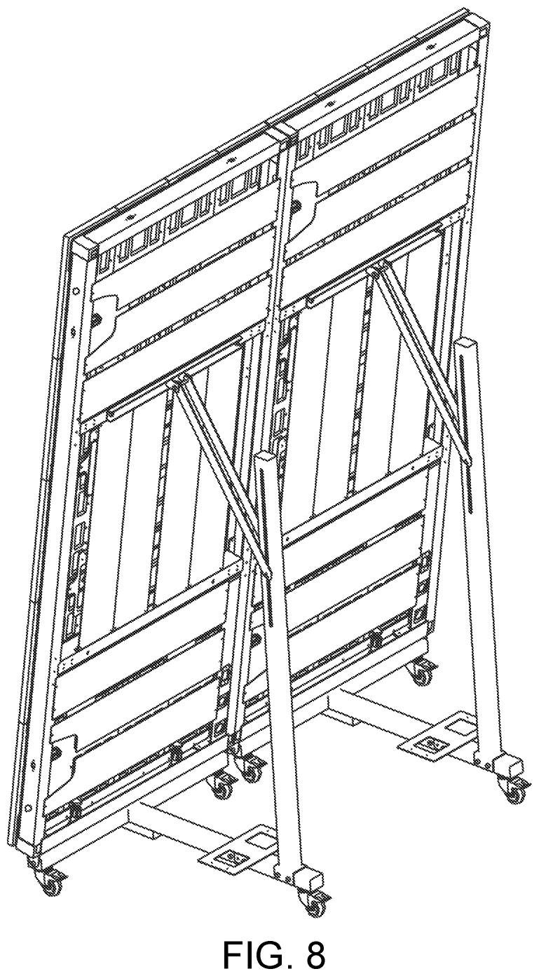

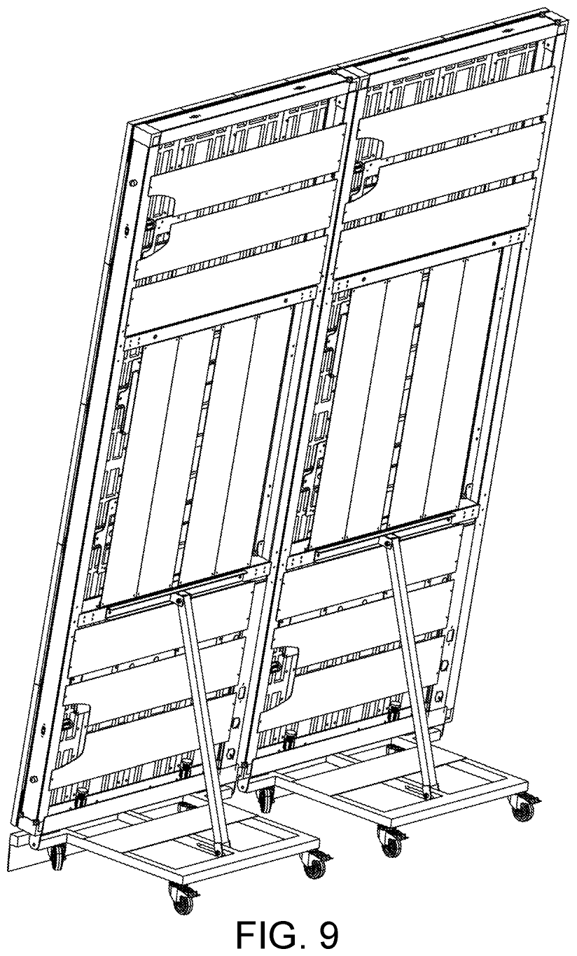

When a plurality of supports need to be spliced, two adjacent third through-holes 431 on two frames 40 of the adjacent supports are aligned, and the two adjacent supports can be quickly spliced by the side quick-connecting member 43. When it is required to detach the adjacent supports, the side quick-connecting member 43 is pressed and rotated to disengage the second clamping shaft along the third through-hole 431. As shown in FIG. 8 and FIG. 9, the structures of the screen support spliced by two supports provided in Embodiment 1 and Embodiment 2 are respectively shown.

The present invention provides an LED screen support, the LED screen support is provided with a fixing bracket 10 and a connecting rod 20, the pitch angle of the frame 40 is adjusted by changing the corresponding fixing position of the connecting rod 20 on the fixing bracket 10, thereby the angle of the LED screen mounted on the frame 40 is changed to meet the needs of different viewing angles. At the same time, the side quick-connecting member 43 is disposed, and the through-hole 431 on the vertical beam of the frame 40 enable two frames 40 of adjacent supports to be quickly spliced after docking, and the spring is used to fix the two adjacent supports. When it is required to detach the adjacent supports, the side quick-connecting member 43 is pressed and the second clamping shaft is withdrawn along the second through-hole.

The descriptions of the above specification and the embodiments are intended to explain the scope of the application, but do not constitute a limitation to the scope of the application. Other embodiments of the present application and modifications, equivalent substitutions, or other improvements of some of the technical features of the present application obtained by a person skilled in the art, based on common knowledge, common technical knowledge and/or prior art in the art, through logical analysis, reasoning or limited experimentation, by the teaching of present application or the above-mentioned embodiments, should also be considered within the scope of the present application.

What is claimed is:

1. An LED screen support, comprising:
a base;
a fixing bracket fixed to the base, wherein the fixing bracket is provided with a plurality of fixing positions;
a connecting rod, wherein the connecting rod is detachably connected to one of the plurality of fixing position; and
a frame for mounting a LED screen, wherein upper and lower sides of the frame are respectively hinged with the connecting rod and the base.

2. The LED screen support according to claim 1, wherein the fixing bracket is fixed to the base in a horizontal direction, and the plurality of fixing positions on the fixing bracket form a sliding groove, and a longitudinal direction of the sliding groove is the same as an extending direction of the fixing bracket, and a first end of the connecting rod slides along the sliding groove and is detachably connected to the sliding groove.

3. The LED screen support according to claim 1, wherein the fixing bracket is fixed to the base in a vertical direction, and the plurality of fixing positions on the fixing bracket form a sliding groove, and a longitudinal direction of the sliding groove is the same as an extending direction of the fixing bracket, and a first end of the connecting rod slides along the sliding groove and is detachably connected to the sliding groove.

4. The LED screen support according to claim 2, wherein the first end of the connecting rod is provided with a sliding shaft, the sliding shaft penetrates the sliding groove and is detachably fixed to the fixing bracket by screwing.

5. The LED screen support according to claim 4, wherein the fixing bracket is provided with a graduated scale around the sliding groove for determining an angular position of the frame.

6. The LED screen support according to claim 5, wherein the base is hinged with a rotating plate, and the rotating plate is fixed to a bottom beam of the frame.

7. The LED screen support according to claim 6, further comprising a bottom quick-connecting member, wherein a first end of the bottom quick-connecting member is provided with a first clamping shaft, and a second end of the bottom quick-connecting member is screwed with a nut, the rotating plate is provided with a first through-hole, and the bottom beam of the frame is provided a second through-hole corresponding to the first through-hole, the first clamping shaft forms a snap-fit relationship with the first through-hole or the second through-hole after the bottom quick-connecting member penetrates the first through-hole and the second through-hole, and the nut is used for fixing the rotating plate and the frame after the first clamping shaft is snapped.

8. The LED screen support according to claim 7, further comprising a side quick-connecting member, wherein the side quick-connecting member is sleeved with a spring, and a first end of the side quick-connecting member is provided with a second clamping shaft, a vertical beam of the frame is provided with a third through-hole, the second clamping shaft is used to form a snap-fit relationship with the third through-hole, and the spring abuts against the vertical beam of the frame and the side quick-connecting member after the second clamping shaft is snapped.

9. The LED screen holder according to claim 8, further comprising a stretching rod and a contour block, wherein the stretching rod is slidably connected to the base, and the contour block is screwed to an end of the stretching rod away from the base and abuts against ground to fix the base.

10. The LED screen support according to claim 9, wherein the base is fixed with a plurality of universal wheels.

11. The LED screen support according to claim 3, wherein the first end of the connecting rod is provided with a sliding shaft, the sliding shaft penetrates the sliding groove and is detachably fixed to the fixing bracket by screwing.

12. The LED screen support according to claim 11, wherein the fixing bracket is provided with a graduated scale around the sliding groove for determining an angular position of the frame.

13. The LED screen support according to claim 12, wherein the base is hinged with a rotating plate, and the rotating plate is fixed to a bottom beam of the frame.

14. The LED screen support according to claim 13, further comprising a bottom quick-connecting member, wherein a first end of the bottom quick-connecting member is provided with a first clamping shaft, and a second end of the bottom quick-connecting member is screwed with a nut, the rotating plate is provided with a first through-hole, and the bottom beam of the frame is provided a second through-hole corresponding to the first through-hole, the first clamping shaft forms a snap-fit relationship with the first through-hole or the second through-hole after the bottom quick-connecting member penetrates the first through-hole and the second through-hole, and the nut is used for fixing the rotating plate and the frame after the first clamping shaft is snapped.

15. The LED screen support according to claim 14, further comprising a side quick-connecting member, wherein the side quick-connecting member is sleeved with a spring, and a first end of the side quick-connecting member is provided with a second clamping shaft; a vertical beam of the frame is provided with a third through-hole, the second clamping shaft is used to form a snap-fit relationship with the third through-hole, and the spring abuts against the vertical beam of the frame and the side quick-connecting member after the second clamping shaft is snapped.

16. The LED screen holder according to claim 15, further comprising a stretching rod and a contour block; wherein the stretching rod is slidably connected to the base, and the contour block is screwed to an end of the stretching rod away from the base and abuts against the base to fix the base.

17. The LED screen support according to claim 16, wherein the base is fixed with a plurality of universal wheels.
